(19) United States
(12) Patent Application Publication
(10) Pub. No.: US 2007/0272919 A1
(43) Pub. Date: Nov. 29, 2007

(54) Stressed organic semiconductor devices

(75) Inventors: Kiyotaka Mori, Cambridge, MA (US); Daniel Hogan, Cambridge, MA (US)

Correspondence Address: RATNERPRESTIA, P.O. BOX 980, VALLEY FORGE, PA, 19482, US

(73) Assignee: Matsushita Electric Industrial Co., Ltd.

(21) Appl. No.: 11/499,311

(22) Filed: Aug. 4, 2006

Related U.S. Application Data
(63) Continuation-in-part of application No. 11/439,935, filed on May 24, 2006.

(51) Int. Cl. H01L 29/08

(52) U.S. Cl. 257/40

(57) ABSTRACT

An organic semiconductor device including: a substrate having a first thermal expansion coefficient; and an organic semiconductor material coupled to the substrate at an interface therebetween. The organic semiconductor material includes a polymer organic semiconductor material and/or an oligomer organic semiconductor material. The organic semiconductor material also has a second thermal expansion coefficient that is different from the first thermal expansion coefficient, such that a mechanical stress is transferred from the substrate to the organic semiconductor material through the interface. This mechanical stress is related to the difference between the first and second thermal expansion coefficients and the change in temperature of the organic semiconductor device.

### CROSS-REFERENCE TO RELATED APPLICATIONS

This application is a Continuation-In-Part of U.S. patent application Ser. No. 11/439,935, filed May 24, 2006, which claimed priority of U.S. patent application Ser. No. 10/807,065, filed Mar. 23, 2004.

### FIELD OF THE INVENTION

The present invention relates generally to organic semiconductor devices and, more particularly, to the use of mechanical force for varying charge carrier mobility in organic semiconductor devices.

### BACKGROUND OF THE INVENTION

Semiconductor-based devices and systems conventionally utilize inorganic semiconductor materials, for example, silicon-based materials. Organic semiconductor materials have the potential to replace conventional inorganic semiconductor materials in a number of applications, and further may provide additional applications to which inorganic semiconductor materials have not been utilized. Such applications may include, for example, display systems, mobile devices, sensor systems, computing devices, signal reception devices, signal transmission devices, and memory devices.

Unfortunately, organic semiconductor materials often have inefficient charge carrier mobility in contrast to inorganic semiconductor materials. This inefficiency occurs because the electrical properties of these organic semiconductor materials are largely limited by intrinsic material properties. Such properties may include, for example, morphology, crystallinity, and packing density of molecules.

Attempts to increase charge carrier mobility in organic semiconductor materials have often proven inadequate or impractical. Therefore, there is a desire for a means of efficiently increasing or decreasing charge carrier mobility in organic semiconductor materials.

### SUMMARY OF THE INVENTION

An exemplary embodiment of the present invention is an organic semiconductor device including: a substrate having a first thermal expansion coefficient; and an organic semiconductor material coupled to the substrate at an interface therebetween. The organic semiconductor material includes a polymer organic semiconductor material and/or an oligomer organic semiconductor material. The organic semiconductor material also has a second thermal expansion coefficient that is different from the first thermal expansion coefficient, such that a mechanical stress is transferred from the substrate to the organic semiconductor material through the interface. This mechanical stress is related to the difference between the first and second thermal expansion coefficients and the change in temperature of the organic semiconductor device.

Another exemplary embodiment of the present invention is an organic semiconductor device including: a substrate having a first thermal expansion coefficient; and an organic semiconductor material coupled to the substrate at an interface therebetween. The organic semiconductor material includes organic semiconductor molecules that each have a longitudinal axis aligned substantially parallel to the interface between the substrate and the organic semiconductor material. The organic semiconductor material also has a second thermal expansion coefficient that is different from the first thermal expansion coefficient, such that a mechanical stress is transferred from the substrate to the organic semiconductor material through the interface. This mechanical stress is related to the difference between the first and second thermal expansion coefficients and the change in temperature of the organic semiconductor device.

A further exemplary embodiment of the present invention is an organic semiconductor device including: a substrate; an organic semiconductor material coupled to the substrate at an interface therebetween; and an actuator adapted to apply a mechanical force to the substrate and/or the organic semiconductor material. The organic semiconductor material includes organic semiconductor molecules that each have a longitudinal axis aligned substantially parallel to the interface between the substrate and the organic semiconductor material. The mechanical force is applied so as to vary the carrier mobility of at least a portion of the organic semiconductor material.

An additional exemplary embodiment of the present invention is an organic semiconductor device including: a substrate; an organic semiconductor material coupled to the substrate at an interface therebetween; and an actuator adapted to apply a bending mechanical force to the substrate and/or the organic semiconductor material. The bending mechanical force applied so as to vary the carrier mobility of at least a portion of the organic semiconductor material.

Yet another exemplary embodiment of the present invention is an organic semiconductor device comprising: a substrate; an organic semiconductor material coupled to the substrate at an interface therebetween; and external force coupling means for coupling an external mechanical force to the substrate and/or the organic semiconductor. The external mechanical force is coupled to the substrate and/or the organic semiconductor so as to vary a carrier mobility of at least a portion of the organic semiconductor material.

It is to be understood that both the foregoing general description and the following detailed description are exemplary, but are not restrictive, of the invention.

### BRIEF DESCRIPTION OF THE DRAWING

Exemplary embodiments of the invention are best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1 is a block diagram of an exemplary organic semiconductor device in accordance with an exemplary embodiment of the present invention;

FIG. 2 is a block diagram of another exemplary organic semiconductor device in accordance with another exemplary embodiment of the present invention;

FIG. 3 is a block diagram of an exemplary organic semiconductor device during various phases of fabrication in accordance with an exemplary embodiment of the present invention;

FIGS. 4A, 4B, and 4C are representations of carrier mobility in various configurations in accordance with exemplary embodiments of the present invention;

FIGS. 5A, 5B, and 5C are block diagrams of exemplary organic semiconductor devices including an actuator in accordance with exemplary embodiments of the present invention;

FIG. 6 is a block diagram of an exemplary packaged organic semiconductor device in accordance with an exemplary embodiment of the present invention;

FIG. 7 is a flow diagram illustrating a method of fabricating an organic semiconductor device in accordance with an exemplary embodiment of the present invention;

FIG. 8 is a flow diagram illustrating another method of fabricating an organic semiconductor device in accordance with another exemplary embodiment of the present invention;

FIG. 9 is a flow diagram illustrating yet another method of fabricating an organic semiconductor device in accordance with another exemplary embodiment of the present invention;

FIG. 10A is a side plan drawing illustrating an exemplary organic semiconductor device according to the present invention in which the organic semiconductor material is in tension;

FIG. 10B is a side plan drawing illustrating an exemplary organic semiconductor device according to the present invention in which the organic semiconductor material is under compression;

FIG. 11A is a side plan drawing illustrating an exemplary molecular configuration of small molecule organic semiconductor material that may be used in exemplary organic semiconductor devices according to the present invention;

FIGS. 11B and 11C are a top plan drawings illustrating alternative exemplary molecular configurations of polymer or oligomer organic semiconductor materials that may be used in exemplary organic semiconductor devices according to the present invention;

FIG. 12A is a side plan drawing illustrating another exemplary organic semiconductor device according to the present invention with actuators to place the organic semiconductor material in tension;

FIG. 12B is a side plan drawing illustrating a further exemplary organic semiconductor device according to the present invention with actuators to place the organic semiconductor material under compression;

FIG. 13A is a side plan drawing illustrating an additional exemplary organic semiconductor device according to the present invention in which a bending force may place the organic semiconductor material in tension;

FIG. 13B is a side plan drawing illustrating yet another exemplary organic semiconductor device according to the present invention in which a bending force may place the organic semiconductor material under compression;

FIGS. 14A and 14D are side plan drawings illustrating yet additional exemplary organic semiconductor devices according to the present invention in which an external force may place the organic semiconductor material in tension; and

FIGS. 14B and 14C are side plan drawings illustrating yet further exemplary organic semiconductor devices according to the present invention in which an external force may place the organic semiconductor material under compression.

### DETAILED DESCRIPTION OF THE INVENTION

Exemplary embodiments of the present invention are described with reference to the figures. One skilled in the art will understand that the scope of the present invention is not limited to these exemplary embodiments. As used herein, organic semiconductor devices refer to various electronic components that include an organic semiconductor material.

The exemplary embodiments of the present invention may use a number of different types of organic semiconductor materials, such as small molecule organic semiconductor materials, oligomer organic semiconductor materials, and polymer organic semiconductor materials. Oligomer organic semiconductor materials include oligomer molecular chains that are longer than the molecules of small molecule organic semiconductor materials. Polymer organic semiconductor materials may include polymer molecular chains that are longer still.

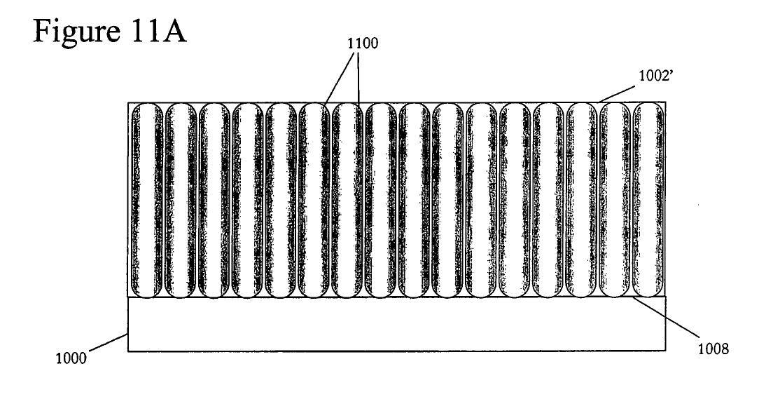

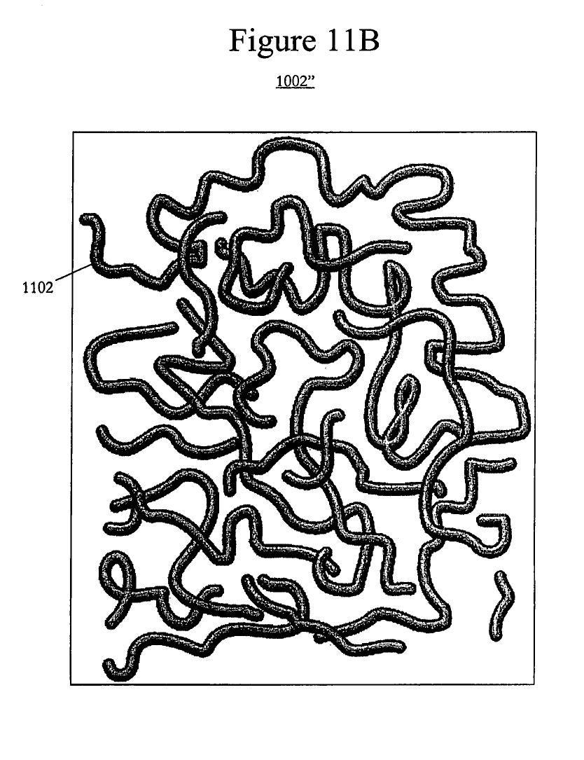

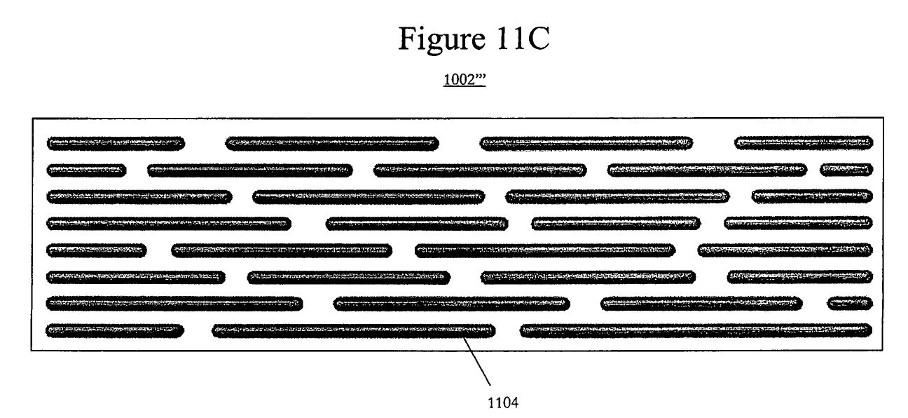

As illustrated in FIG. 11A, organic semiconductor devices using small molecule organic semiconductor materials may be designed so that organic semiconducting molecules 1100 in exemplary small molecule organic semiconductor material 1002′ stand up substantially normal to the surface of the substrate 1000 along interface 1008 between substrate 1000 and exemplary small molecule organic semiconductor material 1002′. An organic semiconductor device using a small molecule organic semiconductor material aligned in this manner is disclosed in U.S. Patent Application No. 2005/0121728 to Z. Bao.

However, small molecule organic semiconductor materials may also be formed such that the organic semiconducting molecules ‘lay down’ so that a long dimension of the molecule (called the longitudinal axis of the molecule herein) is substantially parallel to the surface of the substrate (similar to pasta or needles). This may be accomplished by a number of methods known to those skilled in the art, such as reducing the reaction force between the organic semiconducting molecules and the substrate or hydrophilic treatment of the substrate. Additionally, the longer polymer and oligomer chains of polymer and oligomer organic semiconductor materials typically lay down such that the longitudinal axes of their molecular chains are substantially parallel to the surface of the substrate (similar to pasta or needles). FIG. 11B illustrates a top view organic semiconductor material 1002″ in which organic semiconducting molecules 1102, while not aligned in a specific direction, lay substantially parallel to the surface of the substrate (not shown) on which organic semiconductor material 1002″ is formed). FIG. 11C illustrates a top view of organic semiconductor material 1002′″ in which organic semiconducting molecules 1104 have been aligned in a specific direction substantially parallel to the surface of the substrate (not shown) on which organic semiconductor material 1002′″ is formed.

Organic semiconductor materials having any of these exemplary morphologies may be affected by stress. Compressive stress in a direction parallel to the substrate surface may shorten inter-molecular distance of exemplary small molecule organic semiconductor material 1002′, thereby increasing mobility of carriers parallel to the surface. Similarly, compressive stress in a direction normal to the substrate surface may shorten inter-molecular distance of exemplary organic semiconductor materials 1002″ and 1002′″, thereby increasing the mobility of carriers normal to the surface. Corresponding tensile stresses may decrease the corresponding carrier mobilities in these exemplary organic semiconductor materials. Controlling these stresses may allow for the construction of organic semiconducting devices with dynamically controllable electrical properties.

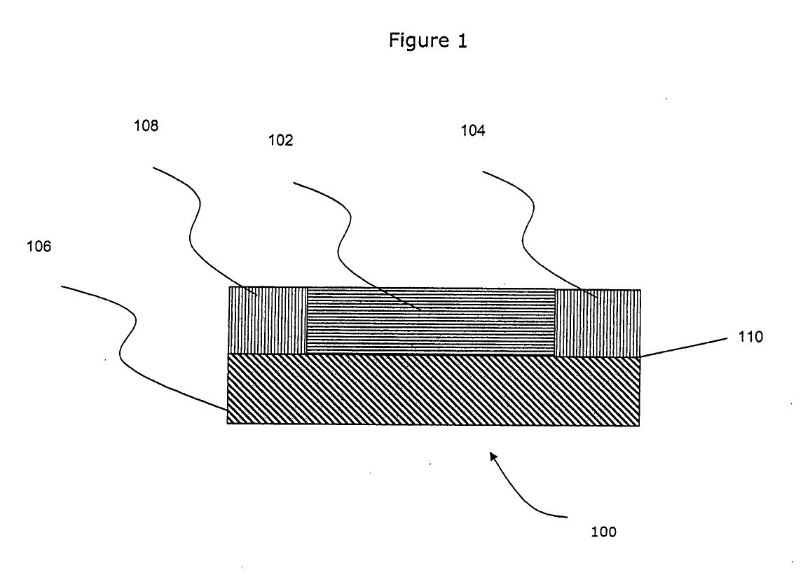

FIG. 1 illustrates an exemplary organic semiconductor device 100 which includes organic semiconductor material 102 supported by substrate 106. Organic semiconductor material 102 desirably includes organic semiconducting molecules aligned to stand up substantially normal to interface 110 between organic semiconductor material 102 and substrate 106. Organic semiconductor device 100 also includes electrodes 104 and 108. During operation, current flows from one electrode (e.g., the source in the case of a transistor) to the other (e.g., the drain in the case of transistor). As discussed below, organic semiconductor device 100 is formed such that a stress is applied to organic semiconductor material 102 through a mechanical interaction occurring at the interface 110 between organic semiconductor material 102 and substrate 106.

More specifically, the mechanical interaction relates to a change in a dimension of substrate 106 (e.g., a change in a dimension that is parallel to interface 110) that results in a corresponding change in a dimension of the organic semiconductor material 102. For example, the mechanical interaction in the lateral structure illustrated in FIG. 1 is related to a decrease in a dimension of substrate 106 that results in a compressive stress being applied to organic semiconductor material 102. This compressive stress leads to negative strain in organic semiconductor material 102, resulting in an increase in carrier mobility (e.g., electron or hole mobility) in organic semiconductor material 102.

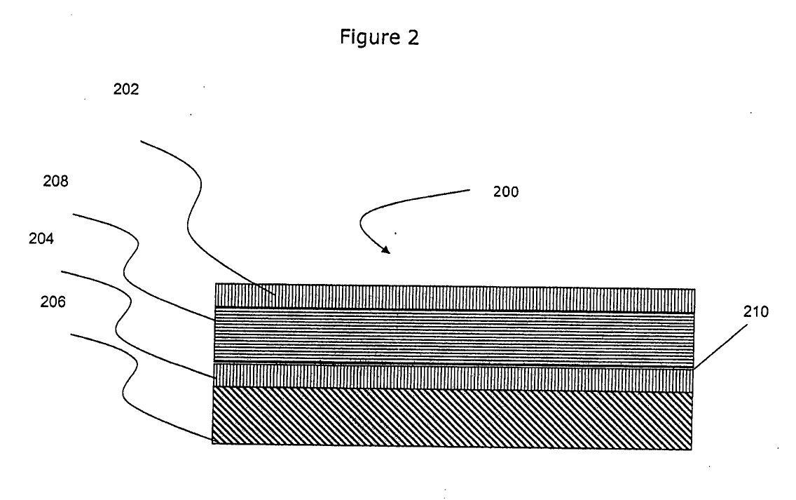

FIG. 2 illustrates exemplary vertically structured organic semiconductor device 200 which includes organic semiconductor material 208 supported by a substrate 206. Organic semiconductor device 200 also includes electrodes 202 and 204. Electrode 204 is positioned between substrate 206 and organic semiconductor material 208. Organic semiconductor material 208 desirably includes organic semiconducting molecules aligned to lay down substantially parallel to interface 210 between organic semiconductor material 208 and electrode 204.

Similar to organic semiconductor device 100 illustrated in FIG. 1, organic semiconductor device 200 is formed such that a stress is applied to organic semiconductor material 208 through a mechanical interaction occurring at the interface 210 between organic semiconductor material 208 and substrate 206. More specifically, the mechanical interaction relates to a change in a dimension of substrate 206 (e.g., elongation of substrate 206 in a direction that is parallel to interface 210) that results in a corresponding change in a dimension of organic semiconductor material 208. Such an elongation of substrate 206 induces a negative strain in organic semiconductor material 208 in the direction of current flow, resulting in an increase in carrier mobility (e.g., electron or hole mobility) in organic semiconductor material 208. Interestingly, the mechanical interaction that ultimately results in the increase in electron mobility may occur even though organic semiconductor material 208 is not in direct contact with substrate 206 (i.e., electrode 204 is positioned between substrate 206 and organic semiconductor material 208).

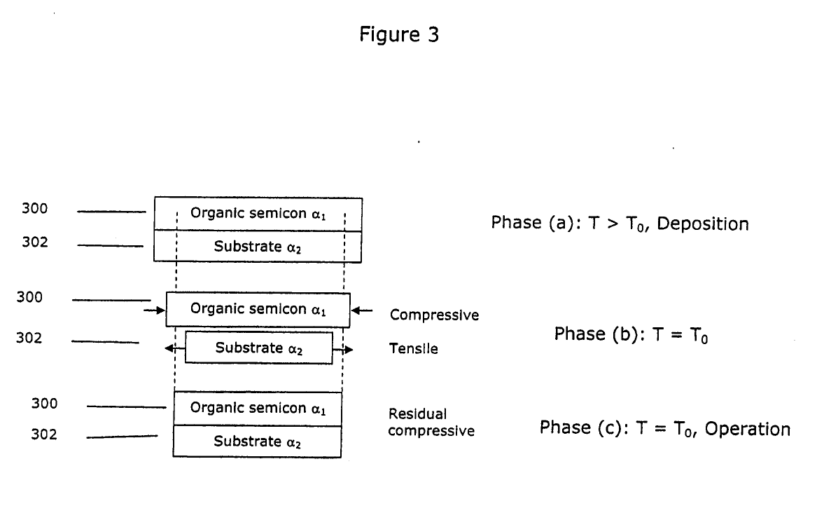

The various exemplary embodiments of the present invention provide a number of methods of affecting carrier (e.g., electron) mobility in an organic semiconductor material through a dimensional change to a substrate. For example, FIG. 3 illustrates the use of differing thermal expansion coefficients for each of a substrate and an organic semiconductor material in order to impact electron mobility of the organic semiconductor material. During a first phase (i.e., phase “(a)”), organic semiconductor material 300 is provided on a substrate 302. Organic semiconductor material 300 has a thermal expansion coefficient α₁ and substrate 302 has a thermal expansion coefficient α₂. During this first phase (i.e., the deposition phase, where organic semiconductor material 300 is deposited and/or annealed on substrate 302), the temperature of organic semiconductor material 300 and substrate 302 is T, which is greater than T₀. T₀ is the temperature at which the organic semiconductor device is operated (e.g., room temperature, ambient temperature, etc.).

Moving now to the second phase (i.e., phase “(b)”) illustrated in FIG. 3, the actual temperature T has cooled to T₀. Assuming that the thermal expansion coefficient α₂ of substrate 302 is higher than the thermal expansion coefficient α₁ of organic semiconductor material 300, substrate 302 shrinks more than organic semiconductor material 300 when cooled down to T₀. This situation is visually represented in that substrate 302 is illustrated as being laterally smaller than organic semiconductor material 300 in the second phase of FIG. 3. Because substrate 302 contracts more than organic semiconductor material 300 during this second phase, a tensile stress in substrate 302 and a corresponding compressive stress is applied to keep the two components (i.e., substrate 302 and organic semiconductor material 300) at the same dimension, attached at the interface.

At the third phase (i.e., phase “(c)”) illustrated in FIG. 3, the device (including organic semiconductor material 300 and substrate 302) is prepared for operation at temperature T₀. At this third phase, the device has reached an equilibrium state where a residual compressive stress is present in organic semiconductor material 300. This residual compressive stress (and corresponding strain) may desirably result in increased carrier mobility in organic semiconductor material 300, if organic semiconductor material 300 is a small molecule organic semiconductor material.

In the exemplary embodiment of the present invention illustrated in FIG. 3, the compressive strain in organic semiconductor material 300 in the third phase may be defined as ΔαΔT, where Δα is the difference in the thermal expansion coefficients of organic semiconductor material 300 and substrate 302 and ΔT is the temperature difference between T and T₀. Assuming Δα is 10 ppm/degree C. and ΔT is 100 degrees C., the compressive strain is 1000 ppm (i.e., 0.1%). Assuming a modulus of organic semiconductor material 300 to be in the range between 1 GPa and 1000 GPa, the compressive stress applied to organic semiconductor material 300 is then between 1 MPa and 1000 MPa. This compressive stress may desirably change the carrier mobility of organic semiconductor material 300 by a factor of between 0.01 and 10.

According to another exemplary embodiment of the present invention, a substrate may be used that has a lower thermal expansion coefficient (i.e., TEC) than the organic semiconductor material, and the organic semiconductor material (e.g., an organic semiconductor film) may be deposited at a temperature that is lower than the operational temperature. According to this embodiment, improved electron mobility in the organic semiconductor material may be achieved for small molecule organic semiconductor materials.

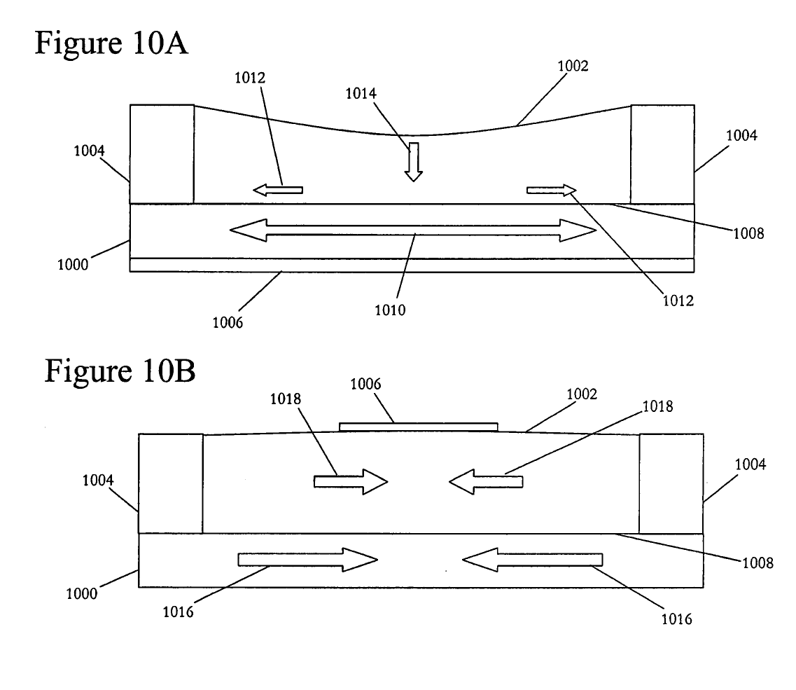

According to another exemplary embodiment of the present invention, the techniques disclosed herein (including the use of thermal expansion coefficients affecting the dimension of the substrate as described above) may be used to apply a tensile stress (as opposed to a compressive stress) to an organic semiconductor material. Such an embodiment may be useful in reducing electron mobility of an organic semiconductor material formed such that the organic semiconducting molecules stand up substantially normal to the interface between the substrate and the organic semiconductor material or increasing the electron mobility of an organic semiconductor material formed such that the organic semiconducting molecules lay down substantially parallel to the interface, as described below with reference to FIG. 10A.

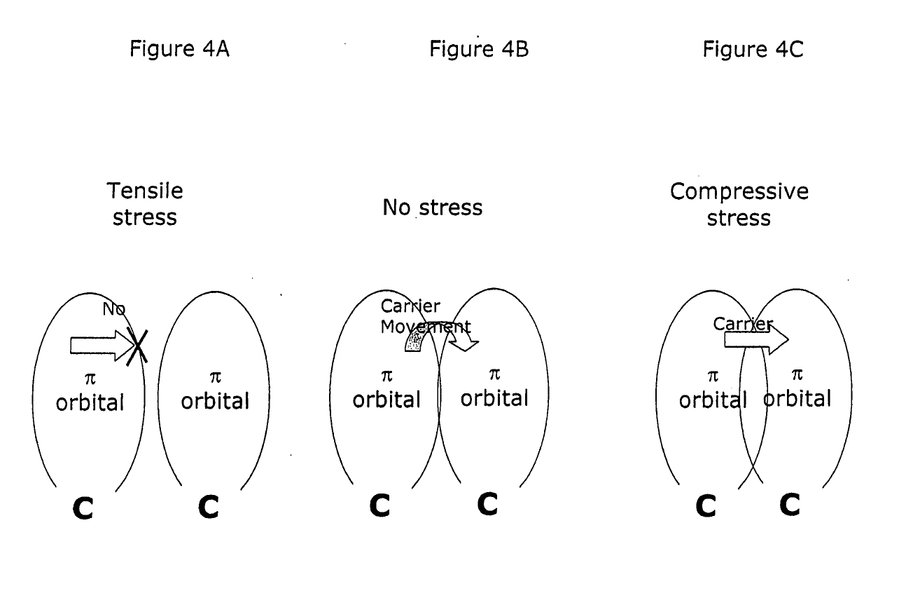

FIGS. 4A, 4B, and 4C are illustrations of carrier mobility (e.g., electron mobility) in an exemplary carbon-based organic semiconductor molecule, where adjacent pi (π) electron orbitals are shown. As illustrated in FIGS. 4A, 4B, and 4C, the shorter the distance between adjacent molecules, or molecular chains, the easier it is to transfer charge carriers (e.g., electrons) between the adjacent molecules, or molecular chains. In FIG. 4A, a tensile stress perpendicular to the long dimension of the molecules, or molecular chains, is intentionally applied to the organic semiconductor material. Therefore, carrier mobility may be substantially reduced. FIG. 4B represents the state of the organic semiconductor material without application of tensile or compressive stress. Carriers move (e.g., hop, tunnel, etc.) from one pi electron orbital to the adjacent orbital. In FIG. 4C, a compressive stress perpendicular to the long dimension of the molecules, or molecular chains, is intentionally applied to the organic semiconductor material. Therefore, carriers may transfer from one pi orbital to an adjacent pi orbital more easily because of the resulting increased carrier mobility.

Thus, as illustrated by FIGS. 4A, 4B, and 4C, the electron mobility of the organic semiconductor material may be enhanced by increasing the overlap of pi electron orbitals of the organic semiconductor material's molecules, or molecular chains, (i.e., as shown in FIG. 4C). This increase of overlap may be described as pi-pi stacking of molecules, or molecular chains, of the organic semiconductor material. Thus, according to certain exemplary embodiments of the present invention, compressive stress is desirably applied in a direction substantially perpendicular to the long dimension of the molecules, or molecular chains, of the organic semiconductor material to enhance overlapping of pi electron orbitals.

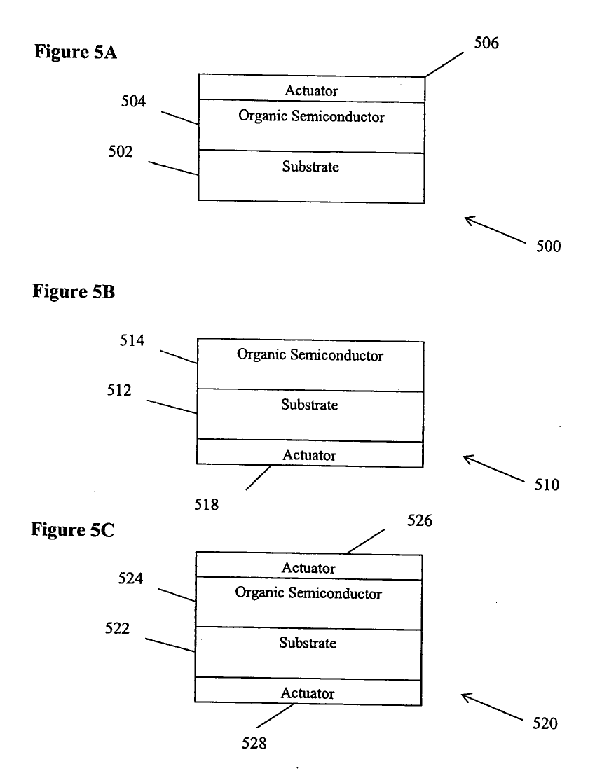

Other exemplary embodiments of the present invention include the use of actuators (or actuator materials) to vary carrier mobility in an organic semiconductor material. Such actuators may include, for example: piezoelectric actuators (i.e., materials generating a mechanical force when a voltage is applied, as in a piezoelectric crystal); piezomagnetic actuators (i.e., materials generating a mechanical force when a magnetic field is applied); electrostrictive actuators (i.e., materials generating a mechanical force when a voltage is applied, as in an electrostrictive crystal such as PMN-PT); magnetostrictive actuators (i.e., materials exhibiting a change in dimension when placed in a magnetic field, also known as the Joule effect); electrostatic actuators (i.e., actuator or material generating an electrostatic force when a voltage is applied); magnetostatic actuators (i.e., actuator generating a mechanical force between two magnetic poles); shape memory alloy actuators (i.e., if the material (e.g., a film) is deformed at a low temperature, upon heating the material will exert a high force to re-attain its as-deposited shape); magnetic shape memory alloy actuators (i.e., smart materials which can undergo large reversible deformations in an applied magnetic field to function as actuators, and compared to ordinary temperature driven shape memory alloys, the magnetic control offers faster response, as the heating and cooling is slower than applying the magnetic field); and electroactive polymer actuators (i.e., a polymer which responds to external electrical stimulation by displaying a significant shape or size displacement). Such actuators may be used to provide a broad range of desired strain values to organic semiconductor materials (e.g., strain values ranging from 0.1-400%). The actuator may be independent of the substrate or the organic semiconductor material as illustrated and described below with reference to FIGS. 5A, 5B, and 5C, or the actuator may be integrated into at least one of the substrate or the organic semiconductor material.

FIG. 5A is a block diagram of exemplary organic semiconductor device 500. Organic semiconductor device 500 includes organic semiconductor material 504 formed on a substrate 502. An actuator 506 is provided on organic semiconductor material 504. For example, actuator 506 may be a piezoelectric actuator. In such an embodiment, upon application of a predetermined voltage to piezoelectric actuator 506, a dimension of piezoelectric actuator 506 changes (e.g., piezoelectric actuator 506 shrinks). This dimensional change in piezoelectric actuator 506 results in the application of a mechanical force at the interface between piezoelectric actuator 506 and organic semiconductor material 504. For example, this mechanical force may be a stress or strain applied to organic semiconductor material 504 that changes the carrier mobility of organic semiconductor material 504 as described above, for example, with respect to FIG. 1. Of course, a piezoelectric actuator is simply an example of a type of actuator 506, and any of a number of alternative actuating materials or mechanisms may be utilized so long as the actuator results in the application of the desired mechanical force (e.g., stress, strain, etc.) at the interface between actuator 506 and organic semiconductor material 504.

FIG. 5B is a block diagram of exemplary organic semiconductor device 510. Organic semiconductor device 510 includes an organic semiconductor material 514 formed on a substrate 512. An actuator 518 is provided below substrate 512. For example, actuator 518 may be a piezomagnetic actuator. In such an embodiment, upon application of a predetermined magnetic field to piezomagnetic actuator 518, a dimension of piezomagnetic actuator 518 changes (e.g., piezomagnetic actuator 518 shrinks) (a predetermined magnetic field is a field that is reasonably predictable, as opposed to random, before it is applied). This dimensional change in piezomagnetic actuator 518 results in the application of a mechanical force at the interface between piezomagnetic actuator 518 and substrate 512.

For example, this mechanical force may be a stress or strain applied to substrate 512. This stress or strain is transferred through substrate 512 to the interface between substrate 512 and organic semiconductor material 514. This stress or strain is applied to organic semiconductor material 514 through the interface between substrate 512 and organic semiconductor material 514, and changes the carrier mobility of organic semiconductor material 514. Of course, a piezomagnetic actuator is simply an example of a type of actuator 518, and any of a number of alternative actuating materials or mechanisms may be utilized so long as the actuator results in the application of the desired mechanical force (e.g., stress, strain, etc.) through substrate 512 and to the interface between substrate 512 and organic semiconductor material 514.

FIG. 5C is a block diagram of exemplary organic semiconductor device 520. Organic semiconductor device 520 includes organic semiconductor material 524 formed on a substrate 522. An actuator 526 is provided on organic semiconductor material 524. Further, an actuator 528 is provided below substrate 522. For example, actuators 526 and 528 may be piezoelectric actuators. In such an embodiment, exemplary piezoelectric actuator 526 may shrink upon application of a predetermined voltage. This dimensional change in piezoelectric actuator 526 results in the application of a mechanical force at the interface between piezoelectric actuator 526 and organic semiconductor material 524. For example, this mechanical force may be a stress or strain applied to organic semiconductor material 524 that changes the carrier mobility of organic semiconductor material 524, as described above.

Further, upon application of a predetermined voltage to exemplary piezoelectric actuator 528, a dimension of piezoelectric actuator 528 changes (e.g., piezoelectric actuator 528 shrinks). This dimensional change in piezoelectric actuator 528 results in the application of a mechanical force at the interface between piezoelectric actuator 528 and substrate 522. For example, this mechanical force may be a stress or strain applied to substrate 522. This stress or strain is transferred through substrate 522 to the interface between substrate 522 and organic semiconductor material 524. This stress or strain is applied to organic semiconductor material 524 through the interface between substrate 522 and organic semiconductor material 524, and changes the carrier mobility of organic semiconductor material 524.

Thus, in the exemplary embodiment of the present invention illustrated in FIG. 5C, carrier mobility of organic semiconductor material 524 is altered through the use of actuator 526 and/or actuator 528.

According to certain other exemplary embodiments of the present invention, the actuator (e.g., piezoelectric actuator, piezomagnetic actuator, or the like) may be integrated into at least one of an organic semiconductor material or a substrate on which the organic semiconductor material is formed. For example, if an organic semiconductor material is formed on a substrate including a piezoelectric material, then the carrier mobility of the organic semiconductor material may be altered by applying a predetermined voltage to the substrate. Similarly, if an organic semiconductor material is formed on a substrate such that the organic semiconductor material includes a piezomagnetic material, then the carrier mobility of the organic semiconductor material may be altered by applying a predetermined magnetic field to the organic semiconductor material. Further still, if an organic semiconductor material is formed on a substrate where both the organic semiconductor material and the substrate include a piezoelectric material, then the carrier mobility of the organic semiconductor material may be altered by applying a predetermined electric field to the organic semiconductor material, the substrate, or both.

Although the exemplary embodiments of the present invention depicted in FIGS. 5A, 5B, and 5C illustrate organic semiconductor devices including only substrates, organic semiconductor materials, and actuators, it is clear that these and other organic semiconductor devices described herein may include a number of other features. For example, the semiconductor materials may include terminals (e.g., two-terminal devices, three-terminal devices, multi-terminal devices, etc.), electrodes, insulating film layers, and other elements (e.g., gate insulator, gate electrode, etc.). In an embodiment utilizing a piezoelectric actuator, such insulation layers may be provided to isolate the applied voltage to the actuator, thereby protecting against potential short-circuiting.

The various exemplary embodiments of the present invention that include actuators relate to actuators that may (either directly or through a mechanical interaction with a substrate) desirably vary the carrier mobility of an organic semiconductor material through actuation of the actuator; however, the reverse process is also contemplated. That is an exemplary actuator may be de-actuated (e.g., the magnetic field removed in the case of a piezomagnetic actuator) to cause the desired mechanical force (e.g., stress, stress strain, or a bending force caused by a change in dimension and/or shape of the substrate and/or organic semiconductor material) to vary the carrier mobility of the organic semiconductor material. Thus, the application of a mechanical force to at least one of the substrate or the organic semiconductor material by the actuator (where the mechanical force varies a carrier mobility of the organic semiconductor material) may be the result a positive actuation of the actuator (e.g., application of a magnetic field in the case of a piezomagnetic actuator) or a negative actuation of the actuator (e.g., removal of a magnetic field in the case of a piezomagnetic actuator).

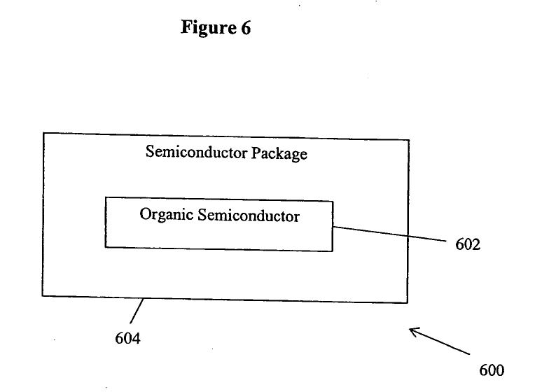

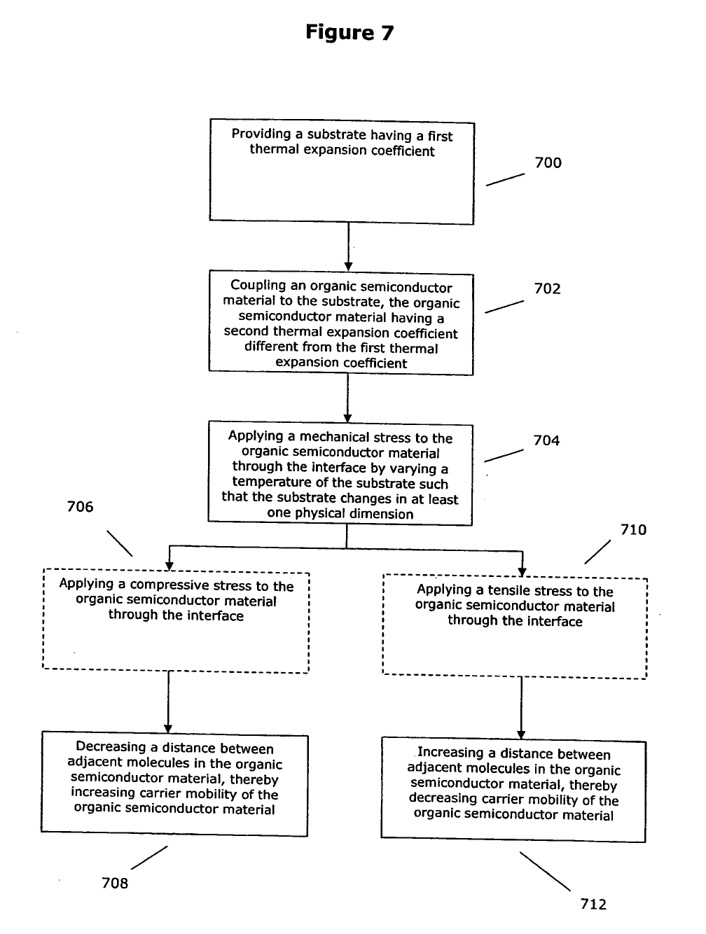

FIG. 6 illustrates exemplary packaged organic semiconductor device 600. Organic semiconductor device 600 includes organic semiconductor material 602 packaged in semiconductor package 604. According to an exemplary embodiment of the present invention, hydrostatic pressure may be applied to organic semiconductor material 602 in package 604. The pressure applied may be sealed into package 604, or may be dynamic. The hydrostatic pressure may be a positive pressure (i.e., compressive) in comparison to atmospheric pressure, or may be a negative pressure (i.e., a vacuum). The hydrostatic pressure may be applied to package 604 through a number of exemplary mechanisms, including, but not limited to, gaseous pressure, liquid pressure, gel pressure, solid pressure, or a combination of these mechanisms. By applying the hydrostatic pressure to organic semiconductor material 602 in package 604, carrier mobility of organic semiconductor material 602 may be affected.

For example, the applied hydrostatic pressure may directly alter the carrier mobility through application of the pressure to organic semiconductor material 602. In such an embodiment, a positive hydrostatic pressure that results in a compressive force being applied to organic semiconductor material 602 may desirably increase carrier mobility of organic semiconductor material 602. Alternatively, a negative hydrostatic pressure that results in tensile force being applied to organic semiconductor material 602 may desirably decrease carrier mobility of organic semiconductor material 602.

Further, the hydrostatic pressure may apply a mechanical force to a substrate in package 604 (the substrate is not shown in FIG. 6), where the mechanical force changes a dimension of the substrate, thereby changing the carrier mobility of organic semiconductor material 602 formed on the substrate, as described above. Further still, the hydrostatic pressure may change the carrier mobility of organic semiconductor material 602 through both of these methods (i.e., through (a) direct application of pressure to organic semiconductor material 602, and (b) application of stress or strain to organic semiconductor material 602 through an interface between organic semiconductor material 602 and a substrate that supports organic semiconductor material 602).

FIG. 7 is a flow diagram illustrating an exemplary method of fabricating an exemplary organic semiconductor device. At step 700, a substrate having a first thermal expansion coefficient is provided. At step 702, an organic semiconductor material is coupled to the substrate at an interface between the two components. The organic semiconductor material has a second thermal expansion coefficient that is different from the first thermal expansion coefficient. At step 704, a mechanical stress is applied to the organic semiconductor material through the interface by varying the temperature of the substrate such that the substrate changes in at least one physical dimension. As used herein, the expression “varying a temperature” may refer to an intentional variation in temperature (e.g., heating, cooling) or may refer to a natural normalization to an environmental or ambient temperature.

If the stress applied at step 704 is a compressive stress, the method proceeds through step 706 to step 708, where a distance between adjacent molecules in the organic semiconductor material is decreased, thereby increasing carrier mobility of the organic semiconductor material. If the stress applied at step 704 is a tensile stress, the method proceeds through step 710 to step 712, where a distance between adjacent molecules in the organic semiconductor material is increased, thereby decreasing carrier mobility of the organic semiconductor material.

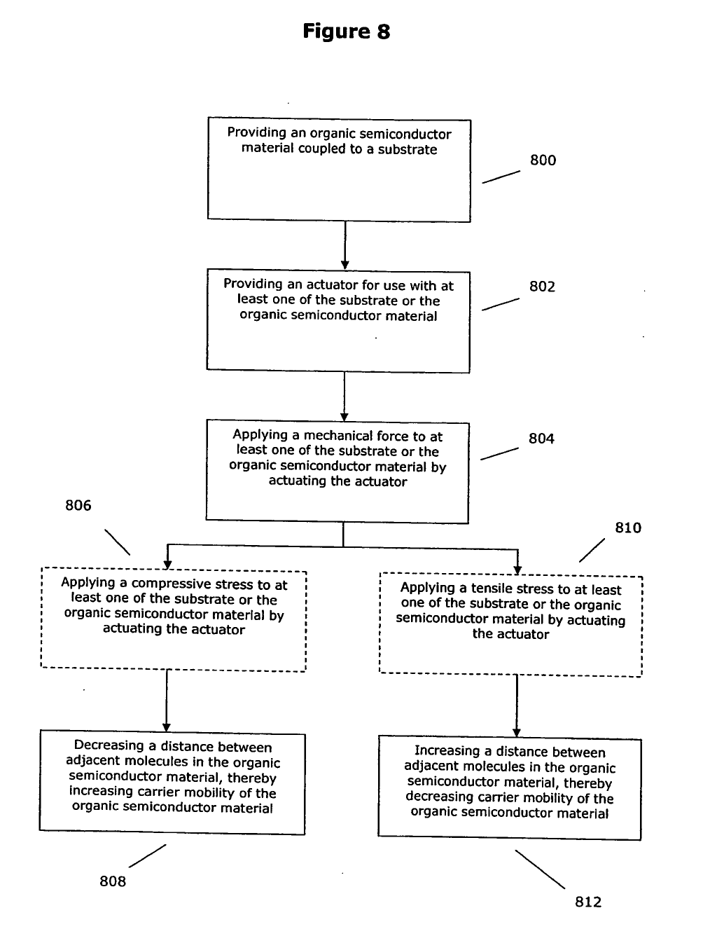

FIG. 8 is a flow diagram illustrating another exemplary method of fabricating an exemplary organic semiconductor device. At step 800, an organic semiconductor material coupled to a substrate is provided. At step 802, an actuator for use with at least one of the substrate or the organic semiconductor material is provided. The actuator is selected from the group comprising piezoelectric actuators, piezomagnetic actuators, magnetostrictive actuators, shape memory alloy actuators, magnetic shape memory alloy actuators, and electroactive polymer actuators. At step 804, a mechanical force is applied to at least one of the substrate or the organic semiconductor material by actuating the actuator. The mechanical force applied by actuating the actuator varies a carrier mobility of the organic semiconductor material.

If the mechanical force applied at step 804 is a compressive stress, the method proceeds through step 806 to step 808, where a distance between adjacent molecules in the organic semiconductor material is decreased, thereby increasing carrier mobility of the organic semiconductor material. If the mechanical force applied at step 804 is a tensile stress, the method proceeds through step 810 to step 812, where a distance between adjacent molecules in the organic semiconductor material is increased, thereby decreasing carrier mobility of the organic semiconductor material.

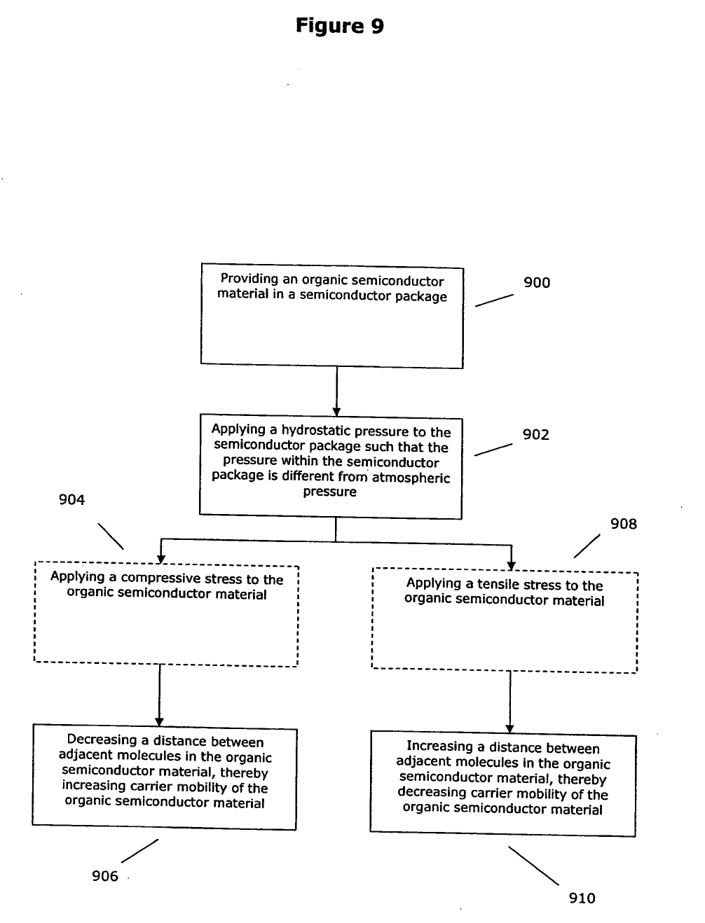

FIG. 9 is a flow diagram illustrating a further exemplary method of fabricating an exemplary organic semiconductor device. At step 900, an organic semiconductor material in a semiconductor package is provided. At step 902, a hydrostatic pressure is applied to the semiconductor package such that the pressure within the semiconductor package is different from atmospheric pressure. The applied hydrostatic pressure varies a carrier mobility of the organic semiconductor material.

If the hydrostatic pressure results in a compressive stress being applied to the organic semiconductor material, the method proceeds through step 904 to step 906, where a distance between adjacent molecules in the organic semiconductor material is decreased, thereby increasing carrier mobility of the organic semiconductor material. If the hydrostatic pressure results in a tensile stress being applied to the organic semiconductor material, the method proceeds through step 908 to step 910, where a distance between adjacent molecules in the organic semiconductor material is increased, thereby decreasing carrier mobility of the organic semiconductor material.

Through the various exemplary embodiments of the present invention described herein, application of a compressive stress to the organic semiconductor material in a direction perpendicular to a long dimension of the organic semiconducting molecules of the organic semiconductor material has primarily been described in connection with an increase in carrier mobility. Likewise, application of a tensile stress to the organic semiconductor material in a direction perpendicular to a long dimension of the organic semiconducting molecules of the organic semiconductor material has primarily been described in connection with a decrease in carrier mobility. However, the present invention is not limited thereto. For example, application of a compressive stress to the organic semiconductor material in a direction parallel to a long dimension of the organic semiconducting molecules of the organic semiconductor material (either directly or through a substrate) may result in a decrease in carrier mobility. Likewise, application of a tensile stress to the organic semiconductor material in a direction parallel to a long dimension of the organic semiconducting molecules of the organic semiconductor material (either directly or through a substrate) may result in an increase in carrier mobility. Additionally, variation of the carrier mobility of an organic semiconductor material may be achieved, for example, based on a phase transformation or a change in the physical configuration (e.g., morphology) of the organic semiconductor material as a result of the application compressive/tensile stress to the organic semiconductor material.

The substrate utilized in connection with the present invention may be any of a number of types of substrate including, for example, a plate substrate, wire substrate, spherical substrate, cubical substrate, and the like.

As described herein, according to certain exemplary embodiments of the present invention, it may be desirable for the substrate to be capable of being dimensionally altered by varying its temperature. The substrate may be made of organic materials that have this property (e.g., Lexan® resin, a high-performance polycarbonate available from GE Plastics). Lexan® resin has been demonstrated to shrink in the range of 10-500 ppm, and even up to 1000 ppm, through thermal treatment. This shrinkage may desirably be used to apply stress to the organic semiconductor material.

FIG. 10A illustrates another exemplary organic semiconductor device according to the present invention. This exemplary organic semiconductor device includes: substrate 1000; organic semiconductor material 1002 formed on substrate 1000; electrodes 1004 coupled to both substrate 1000 and organic semiconductor material 1002; and temperature control element 1006 coupled to substrate 1000. Substrate 1000 has a first thermal expansion coefficient and organic semiconductor material 1002 has a second thermal expansion coefficient, which is different from the first thermal expansion coefficient of the substrate.

FIG. 10B illustrates a similar exemplary organic semiconductor device in which temperature control element 1006 is coupled to organic semiconductor material 1002 instead of substrate 1000.

In the exemplary organic semiconductor devices of FIGS. 10A and 10B, mechanical stress may be transferred from substrate 1000 to organic semiconductor material 1002 through interface 1008 therebetween. This mechanical stress may result, when a change in temperature of the organic semiconductor device occurs, due to the difference between the first thermal expansion coefficient and the second thermal expansion coefficient.

As shown in FIG. 10A, the difference in thermal expansion 1010 of substrate 1000 and thermal expansion 1012 of organic semiconductor material 1002 may result in a tensile stress substantially parallel to interface 1008 and corresponding contraction 1014 of at least a portion of organic semiconductor material 1002 in a direction substantially parallel to interface 1008. While the tensile stress may decrease the carrier mobility of a small molecule organic semiconductor material formed such that the organic semiconductor molecules stand up substantially normal to interface 1008, corresponding contraction 1014 may increase the carrier mobility of small molecule, polymer, and oligomer organic semiconductor materials formed such that the organic semiconductor molecules lay down substantially parallel to interface 1008.

As shown in FIG. 10B, the difference in thermal contraction 1016 of substrate 1000 and thermal contraction 1018 of organic semiconductor material 1002 may result in a compressive force substantially parallel to interface 1008. This compressive force may increase the carrier mobility of small molecule organic semiconductor materials formed such that the organic semiconductor molecules stand up substantially normal to interface 1008. This compressive force may also result in the expansion of at least a portion of organic semiconductor material 1002 in a direction substantially normal to interface 1008 and, thus, may decrease the carrier mobility of small molecule, polymer, and oligomer organic semiconductor materials formed such that the organic semiconductor molecules lay down substantially parallel to interface 1008.

The change in temperature may occur due changing ambient conditions, as described above, or may result from heating of the device during operation. However, as shown in FIGS. 10A and 10B, temperature control element 1006 may be used to actively control the temperature and, thus, the carrier mobility of organic semiconductor material 1002. Temperature control element 1006 may include a resistive heating element to raise the temperature of the exemplary organic semiconductor device and rely on ambient conditions for lowering the temperature. Alternatively, a thermoelectric cooler may be used to quickly and accurately both raise and lower the temperature of the exemplary organic semiconductor device.

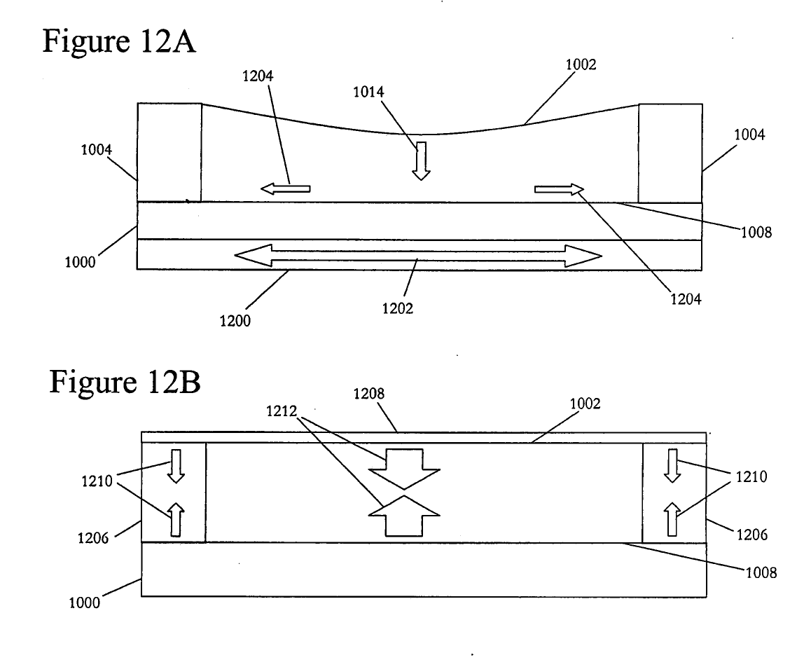

FIGS. 12A and 12B illustrate further exemplary organic semiconductor devices including actuators.

The exemplary organic semiconductor device of FIG. 12A includes actuator 1200 coupled to substrate 1000. This exemplary organic semiconductor device is illustrated with actuator 1200 applying tensile stress 1202 substantially parallel to interface 1008. This tensile stress is transmitted through substrate 1000 and interface 1008 to induce tensile stress 1204 and corresponding contraction 1014 in organic semiconductor material 1002. One skilled in the art will understand that actuator 1200 may be used to apply a compressive force substantially parallel to interface 1008 instead. Also, one skilled in the art will understand that actuator 1200 may be coupled directly to organic semiconductor material 1002 or may be formed within either substrate 1000 or organic semiconductor material 1002, as described above with reference to FIGS. 5A-C.

The exemplary organic semiconductor device of FIG. 12B includes actuators 1206 which are coupled between substrate 1000 and rigid layer 1208. This exemplary organic semiconductor device is illustrated with actuators 1206 applying compressive forces 1210 to pull rigid layer 1208 in a direction substantially normal to interface 1008. This results in compressive force 1212 in organic semiconductor material 1002. One skilled in the art will understand that, if rigid layer 1208 is connected to organic semiconductor material 1002, then actuators 1206 may also be used to push rigid layer 1208 away from interface 1008 and, thus, apply a tensile stress substantially normal to interface 1008 in organic semiconductor material 1002. Also, one skilled in the art will understand that actuators 1206 may be formed within organic semiconductor material 1002.

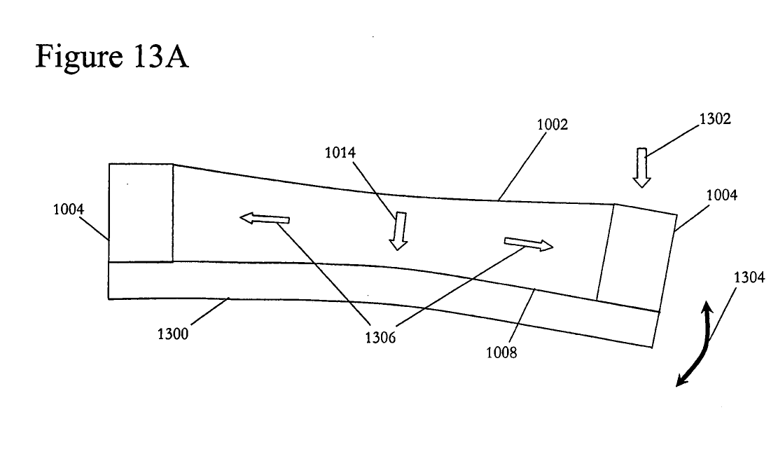

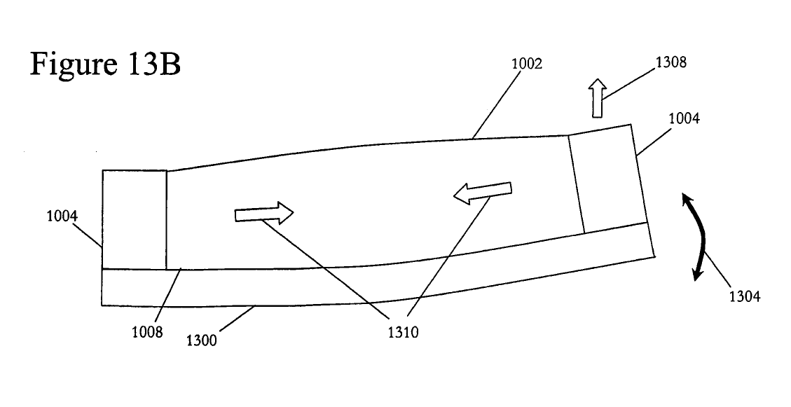

FIGS. 13A and 13B illustrate additional exemplary organic semiconductor devices. These exemplary organic semiconductor devices include flexible substrate 1300, which may be bent in the plane of the page as shown by arrow 1304.

FIG. 13A illustrates flexible substrate 1300 bending from downward force 1302 such that interface 1008 presents a convex surface toward organic semiconductor material 1002. Because organic semiconductor material 1002 is on the outside of the resulting curve of the surface, it is stretched by tensile stress 1306. This stretching leads to corresponding contraction 1014 normal to interface 1008 in at least a portion of organic semiconductor material 1002. As described above, if organic semiconductor material 1002 is an organic semiconductor material formed such that the organic semiconductor molecules lay down substantially parallel to interface 1008, corresponding contraction 1014 may lead to an increase in the carrier mobility of organic semiconductor material 1002; however, if organic semiconductor material 1002 is an organic semiconductor material formed such that the organic semiconductor molecules stand up substantially normal to interface 1008, tensile stress 1306 may lead to a decrease in the carrier mobility of the organic semiconductor material 1002.

FIG. 13B illustrates flexible substrate 1300 bending from upward force 1308 such that interface 1008 presents a concave surface toward organic semiconductor material 1002. Because organic semiconductor material 1002 is on the inside of the resulting curve of the surface, it is compressed by compressive force 1310. This compression may lead to a corresponding expansion normal to interface 1008 in at least a portion of organic semiconductor material 1002. As described above, if organic semiconductor material 1002 is an organic semiconductor material formed such that the organic semiconductor molecules lay down substantially parallel to interface 1008, this corresponding expansion may lead to a decrease in the carrier mobility of organic semiconductor material 1002; however, if organic semiconductor material 1002 is an organic semiconductor material formed such that the organic semiconductor molecules stand up substantially normal to interface 1008, compressive force 1310 may lead to an increase in the carrier mobility of the organic semiconductor material 1002.

It is noted that FIGS. 13A and 13B illustrate downward force 1302 and upward force 1308, respectively, as being transmitted to flexible substrate 1300 from an external source. Such an external force may be coupled to the substrate by means of an external force coupling means, such a rigid bar, an elastic bar, a thread, a wire, a ribbon, a chain, a spring, or a combination thereof. Alternatively, the bending of flexible substrate 1300 may be caused by an actuator coupled to flexible substrate 1300 or organic semiconductor material 1002 (or formed within one of them), as described above with reference to FIGS. 5A-C, 12A, and 12B.

One skilled in the art will understand that by actively controlling the bending of flexible substrate 1300, the carrier mobility of organic semiconductor material 1002 may be dynamically varied.

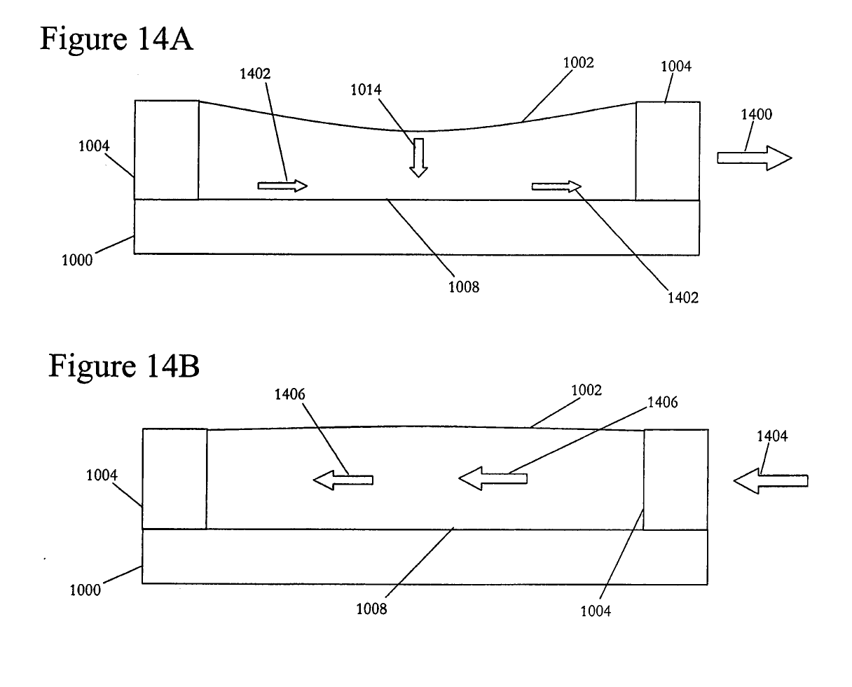

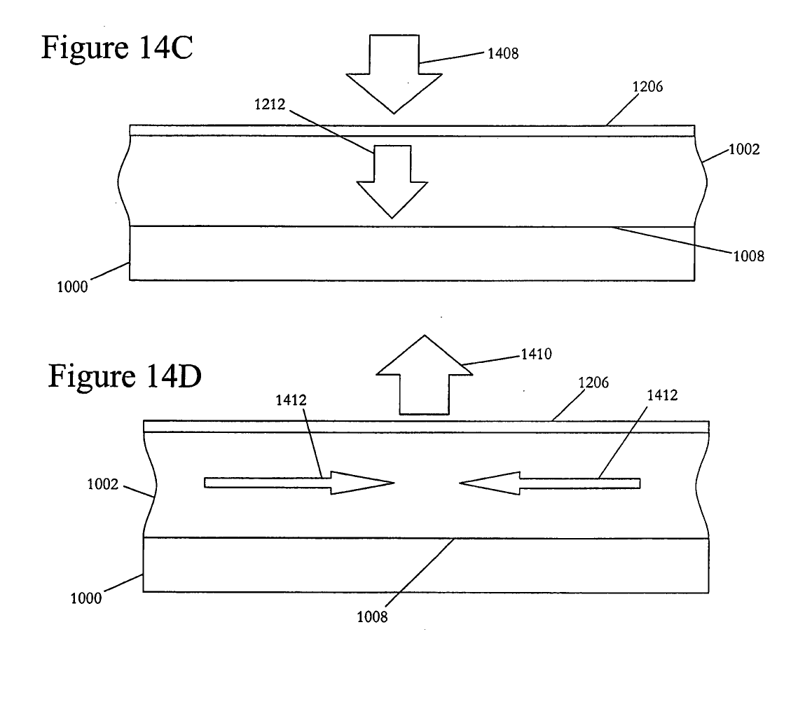

FIGS. 14A-D illustrate yet further exemplary organic semiconductor devices according to the present invention in which the carrier mobility of organic semiconductor material 1002 may be varied by an external force. As in the exemplary organic semiconductor devices of FIGS. 13A and 13B, these external forces may be applied to organic semiconductor material 1002 by a number of external force coupling means (not shown), such as rigid bars, elastic bars, threads, wires, ribbons, chains, springs, or combinations thereof. These external force coupling means may be coupled to substrate 1000 or may be coupled directly to organic semiconductor material 1002. One skilled in the art will understand that any of these external force coupling means may be used to apply either a tensile stress (as shown in FIGS. 14A and 14D) or a compressive force (as shown in FIGS. 14B and 14C) by pulling on either substrate 1000 or organic semiconductor material 1002; however, it is noted that some external force coupling means, such as threads, may not have enough rigidity to be used to apply tensile stresses and compressive forces by pushing on substrate 1000 or organic semiconductor material 1002.

FIG. 14A illustrates an exemplary organic semiconductor device subjected to external tensile stress 1400, which is applied in a direction substantially parallel to interface 1008 between substrate 1000 and organic semiconductor material 1002. This external tensile stress desirably results in tensile stress 1402 within organic semiconductor material 1002 in a direction substantially parallel to interface 1008, and may result in corresponding contraction 1014 of at least a portion of organic semiconductor material 1002 in a direction substantially normal to interface 1008.

FIG. 14B illustrates an exemplary organic semiconductor device subjected to external compressive force 1404, which is applied in a direction substantially parallel to interface 1008. This external compressive force desirably results in compressive force 1406 within organic semiconductor material 1002 in a direction substantially parallel to interface 1008, and may result in a corresponding expansion of at least a portion of organic semiconductor material 1002 in a direction substantially normal to interface 1008.

FIG. 14C illustrates an exemplary organic semiconductor device subjected to external compressive force 1408, which is illustrated as applied to rigid layer 1206 in a direction substantially normal to interface 1008. This rigid layer may be thought of as part of the external force coupling means. Alternatively, if organic semiconductor material 1002 is rigid enough, rigid layer 1206 may be omitted. External compressive force 1408 desirably results in compressive force 1212 within organic semiconductor material 1002 in a direction substantially normal to interface 1008, and may result in a corresponding expansion of at least a portion of organic semiconductor material 1002 in a direction substantially parallel to interface 1008.

FIG. 14D illustrates an exemplary organic semiconductor device subjected to external tensile stress 1410, which is illustrated as being applied to rigid layer 1206 in a direction substantially normal to interface 1008. As in the exemplary organic semiconductor device of FIG. 14C, if organic semiconductor material 1002 is rigid enough, rigid layer 1206 may be omitted. This external tensile stress desirably results in a tensile stress within organic semiconductor material 1002 in a direction substantially normal to interface 1008, and may result in corresponding contraction 1412 of at least a portion of organic semiconductor material 1002 in a direction substantially parallel to interface 1008.

The amount of external force applied to the exemplary organic semiconductor devices of FIGS. 14A-D (as well as 13A and 13B) may be set to achieve a desired carrier mobility in organic semiconductor material 1002 or it may be actively controlled to dynamically vary the carrier mobility in organic semiconductor material 1002. Alternatively, by measuring changes in the carrier mobility of organic semiconductor material 1002, the amount of compressive force or tensile stress applied to the exemplary organic semiconductor device may be determined. Thus, these exemplary organic semiconductor devices may be used as force and/or stress gauges.

Although the exemplary device structures and fabrication methods described herein depict direct connections between the various components of an exemplary organic semiconductor device (e.g., a direct connection between a substrate and an organic semiconductor material, a direct connection between an actuator and either of a substrate or an organic semiconductor material, etc.), the present invention is not limited to such direct configurations. The inventive concepts disclosed may be applied to a diverse set of device structures and fabrication methods. For example, insulating layers, electrical connections, and other elements may be provided between the various structural components. Thus, as used herein, the term “coupling” does not necessarily refer to a direct connection; rather, the term may apply to any connection that facilitates the desired mechanical interaction and ultimate shift in carrier mobility of the organic semiconductor material.

These inventive concepts may be applied to a broad range of traditional and non-traditional semiconductor applications. More specifically, the concepts disclosed herein may be suitable to any application utilizing organic semiconductor materials.

Although the invention is illustrated and described above with reference to specific embodiments, the invention is not intended to be limited to the details shown. Rather, various modifications may be made in the details within the scope and range of equivalents of the claims and without departing from the invention.

What is claimed:

1. An organic semiconductor device comprising:
a substrate having a first thermal expansion coefficient; and
an organic semiconductor material coupled to the substrate at an interface therebetween, the organic semiconductor material:
including at least one of a polymer organic semiconductor material or an oligomer organic semiconductor material; and
having a second thermal expansion coefficient that is different from the first thermal expansion coefficient, such that a mechanical stress is transferred from the substrate to the organic semiconductor material through the interface, the mechanical stress being related to the difference between the first thermal expansion coefficient and the second thermal expansion coefficient and a change in temperature of the organic semiconductor device.

2. The organic semiconductor device of claim 1, wherein the mechanical stress is a tensile stress transferred from the substrate to the organic semiconductor material through the interface.

3. The organic semiconductor device of claim 2, wherein the tensile stress causes contraction of the organic semiconductor material in a direction substantially normal to the interface, decreasing a distance between adjacent organic semiconductor molecules in the organic semiconductor material to increase carrier mobility of the organic semiconductor material.

4. An organic semiconductor device comprising:
a substrate having a first thermal expansion coefficient; and
an organic semiconductor material coupled to the substrate at an interface therebetween, the organic semiconductor material:
including a plurality of organic semiconductor molecules, each organic semiconductor molecule having a longitudinal axis aligned substantially parallel to the interface between the substrate and the organic semiconductor material; and
having a second thermal expansion coefficient that is different from the first thermal expansion coefficient, such that a mechanical stress is transferred from the substrate to the organic semiconductor material through the interface, the mechanical stress being related to the difference between the first thermal expansion coefficient and the second thermal expansion coefficient and a change in temperature of the organic semiconductor device.

5. The organic semiconductor device of claim 4, wherein the organic semiconductor material includes at least one of a small molecule organic semiconductor material, a polymer organic semiconductor material, or an oligomer organic semiconductor material.

6. The organic semiconductor device of claim 4, wherein the mechanical stress is a tensile stress transferred from the substrate to the organic semiconductor material through the interface.

7. The organic semiconductor device of claim 6, wherein the tensile stress causes contraction of the organic semiconductor material in a direction substantially normal to the interface, decreasing a distance between adjacent organic semiconductor molecules in the organic semiconductor material to increase carrier mobility of the organic semiconductor material.

8. The organic semiconductor device of claim 4, further comprising a temperature control element thermally coupled to at least one of the substrate or the organic semiconductor material.

9. The organic semiconductor device of claim 8, wherein the temperature control element includes at least one of a resistive heating element or a thermoelectric cooler.

10. An organic semiconductor device comprising:
a substrate;
an organic semiconductor material coupled to the substrate at an interface therebetween, the organic semiconductor material including a plurality of organic semiconductor molecules, each organic semiconductor molecule having a longitudinal axis aligned substantially parallel to the interface between the substrate and the organic semiconductor material; and
an actuator adapted to apply a mechanical force to at least one of the substrate or the organic semiconductor material to vary a carrier mobility of at least a portion of the organic semiconductor material.

11. The organic semiconductor device of claim 10, wherein the organic semiconductor material includes at least one of a small molecule organic semiconductor material, a polymer organic semiconductor material, or an oligomer organic semiconductor material.

12. The organic semiconductor device of claim 10, wherein the actuator is selected from the group comprising piezoelectric actuators, piezomagnetic actuators, electrostrictive actuators, magnetostrictive actuators, electrostatic actuators, magnetostatic actuators, shape memory alloy actuators, magnetic shape memory alloy actuators, and electroactive polymer actuators.

13. The organic semiconductor device of claim 10, wherein the actuator is integrated into at least one of the substrate or the organic semiconductor material.

14. The organic semiconductor device of claim 10, wherein:
the mechanical force is a tensile stress in a direction substantially parallel to the interface; and
the tensile stress contracts at least a portion of the organic semiconductor material in a direction substantially normal to the interface, thereby decreasing a distance between adjacent organic semiconductor molecules in the organic semiconductor material and increasing carrier mobility of the organic semiconductor material.

15. The organic semiconductor device of claim 10, wherein:
the mechanical force is a compressive force in a direction substantially normal to the interface; and
the compressive force compresses at least a portion of the organic semiconductor material in the direction substantially normal to the interface, thereby decreasing a distance between adjacent organic semiconductor molecules in the organic semiconductor material and increasing carrier mobility of the organic semiconductor material.

16. An organic semiconductor device comprising:
a substrate;
an organic semiconductor material coupled to the substrate at an interface therebetween; and
an actuator adapted to apply a bending mechanical force to at least one of the substrate or the organic semiconductor material to vary a carrier mobility of at least a portion of the organic semiconductor material.

17. The organic semiconductor device of claim 16, wherein the organic semiconductor material includes at least one of a small molecule organic semiconductor material, a polymer organic semiconductor material, or an oligomer organic semiconductor material.

18. The organic semiconductor device of claim 16, wherein the actuator is selected from the group comprising piezoelectric actuators, piezomagnetic actuators, electrostrictive actuators, magnetostrictive actuators, electrostatic actuators, magnetostatic actuators, shape memory alloy actuators, magnetic shape memory alloy actuators, and electroactive polymer actuators.

19. The organic semiconductor device of claim 16, wherein:
the organic semiconductor material includes a plurality of organic semiconductor molecules, each organic semiconductor molecule having a longitudinal axis aligned substantially parallel to the interface between the substrate and the organic semiconductor material; and
the bending mechanical force contracts at least a portion of the organic semiconductor material in a direction substantially normal to the interface, decreasing a distance between adjacent organic semiconductor molecules in the organic semiconductor material, thereby increasing carrier mobility of the organic semiconductor material.

20. The organic semiconductor device of claim 16, wherein:
the organic semiconductor material includes small molecule organic semiconductor material; and
the bending mechanical force compresses at least a portion of the organic semiconductor material in a direction substantially tangential to the interface, decreasing a distance between adjacent organic semiconductor molecules in the organic semiconductor material, thereby increasing carrier mobility of the organic semiconductor material.

21. The organic semiconductor device of claim 16, wherein the actuator is integrated into at least one of the substrate or the organic semiconductor material.

22. An organic semiconductor device comprising:
a substrate;
an organic semiconductor material coupled to the substrate at an interface therebetween; and
external force coupling means for coupling an external mechanical force to at least one of the substrate or the organic semiconductor, the coupled external mechanical force varying a carrier mobility of at least a portion of the organic semiconductor material.

23. The organic semiconductor device of claim 22 wherein the external force coupling means includes at least one of a rigid bar, an elastic bar, a thread, a wire, a ribbon, a chain, or a spring.

24. The organic semiconductor device of claim 23 wherein the coupled external mechanical force applies at least one of:
compressive force in a direction substantially parallel to the interface to the substrate;
compressive force in the direction substantially parallel to the interface to the organic semiconductor material;
compressive force in the direction substantially normal to the interface to the organic semiconductor material;
tensile stress in the direction substantially parallel to the interface to the substrate;
tensile stress in the direction substantially parallel to the interface to the organic semiconductor material;
tensile stress in the direction substantially normal to the interface to the organic semiconductor material;
bending mechanical force to the substrate; or
bending mechanical force to the organic semiconductor material.
